(19) United States
(12) Patent Application Publication
(10) Pub. No.: US 2018/0024191 A1
(43) Pub. Date: Jan. 25, 2018

(54) INTEGRATED CIRCUIT STRUCTURE

(71) Applicant: ALi Corporation, Hsinchu (TW)

(72) Inventor: Chi-Bin Chen, Hsinchu (TW)

(73) Assignee: ALi Corporation, Hsinchu (TW)

(21) Appl. No.: 15/584,971

(22) Filed: May 2, 2017

(30) Foreign Application Priority Data
Jul. 19, 2016 (CN) 201610567623.6

(51) Int. Cl. G01R 31/319; G01R 19/00; G01R 17/02; G01R 19/165; G01R 35/04; G01R 35/00

(52) U.S. Cl. CPC G01R 31/3191; G01R 35/04; G01R 35/007; G01R 17/02; G01R 19/165; G01R 19/0069; G01R 31/31915

(57) ABSTRACT

An integrated circuit structure including a reference circuit and at least two core circuits is provided. The reference circuit provides a reference current. The at least two core circuits are coupled to the reference circuit for receiving the reference current. Each of the core circuits includes a current-calibration circuit. The current-calibration circuit generates a bias current according to the reference current in the core circuit. The core circuits use the bias current to replace the reference circuit. In an IC test process, the reference circuit provides the reference current through the pin of the integrated circuit electronically connected to the external impedance. After the IC test process, the connection of the reference circuit and the pin of the integrated circuit is disconnected.

### CROSS-REFERENCE TO RELATED APPLICATION

This application claims the priority benefit of China application serial no. 201610567623.6, filed on Jul. 19, 2016. The entirety of the above-mentioned patent application is hereby incorporated by reference herein and made a part of this specification.

### BACKGROUND OF THE INVENTION

### Field of the Invention

The invention relates to an integrated circuit technique, and particularly relates to an integrated circuit structure using a bias current generated by a current-calibration circuit to replace a reference current.

### Description of Related Art

An integrated circuit (IC) requires a stable reference current to ensure operation stability of various core circuits or silicon intellectual property (SIP) devices in the IC. A general IC may generate a reference voltage through a bandgap reference circuit, and by connecting a pin of the IC to an accurate external resistance, an accurate reference current is generated.

However, although the bandgap reference circuit is configured in the IC, a current path between the bandgap reference circuit and each of the core circuits or the SIP devices may still interfered by noise, such that the reference current may jittered due to the interference, which decreases a signal performance. The current path may interfered by the noise which from a power terminal/ground terminal of each of the SIP devices. Moreover, in order to connect the external resistance for generating the reference current, the extra pin of the IC is required. External noises may also be coupled to the pin which connected to the external resistance to influence the quality of the reference current. Therefore, how to generate an accurate and clean reference current becomes an important issue to be achieved by various IC manufacturers.

### SUMMARY OF THE INVENTION

The invention is directed to an integrated circuit (IC) structure, in which a bias current generated by a current-calibration circuit is adopted to replace an original reference current, so as to obtain a stable current signal that will not interfered by noise.

The invention provides an IC structure including a reference circuit and at least two core circuits. The reference circuit generates a reference current. The core circuits are coupled to the reference circuit for receiving the reference current. Each of the core circuits includes a current-calibration circuit. The current-calibration circuit generates a bias current according to the reference current. The core circuit uses the bias current as reference, so as to replace the reference current which generated by the reference circuit. In the IC test process, the reference circuit is electrically connected to an external impedance through a pin of the IC structure to generate the reference current. After the IC test process, a connection between the reference circuit and the pin of the IC structure is disconnected.

In an embodiment of the invention, the current-calibration circuit includes a voltage generator, a current generator, a digital-control current mirror and a current comparator. The voltage generator is configured to generate an internal reference voltage. The current generator is coupled to the voltage generator, and generates an internal reference current according to the internal reference voltage. The digital-control current mirror is coupled to the current generator, and the digital-control current mirror generates a calibrating current according to the internal reference current. The current comparator is coupled to the digital-control current mirror. The current comparator is configured to compare the reference current with the calibrating current. When the current-calibration circuit is activated, the digital-control current mirror adjusts a current value of the calibrating current. The digital-control current mirror generates the bias current according to a comparison result of the current comparator, where a current value of the bias current is substantially the same as a present current value of the reference current.

According to the above description, in the IC structure of the invention, the current-calibration circuit is configured in each of the core circuits, such that each of the core circuits is adapted to generate the bias current generated by the current-calibration circuit according to the reference current, so as to replace the original reference current generated by the bandgap reference circuit. Besides that the reference current generated by the IC of the invention is not influenced by a variation of an absolute temperature and a variation of a system voltage, a process offset is also eliminated to obtain the stable reference current that is not interfered by noise. Moreover, the IC structure of the invention may remove the external impedance after the IC test process or release the pin for the use of other digital circuit, so as to reduce the number of pins used in the IC and save the chip size.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an integrated circuit (IC) structure according to a first embodiment of the invention.

FIG. 2 is a block diagram of a current-calibration circuit according to the first embodiment of the invention.

FIG. 3 is a schematic diagram of an IC structure according to a second embodiment of the invention.

FIG. 4 is a schematic diagram of an IC structure according to a third embodiment of the invention.

### DESCRIPTION OF EMBODIMENTS

In order to ensure core circuits in an integrated circuit (IC) structure to obtain a stable reference current, besides a reference circuit in the IC structure to generate a reference current, in the present embodiment, a current-calibration circuit is also configured in the core circuits, such that the current-calibration circuit of each of the core circuits is adapted to generate a bias current according to the reference current. In this way, the core circuit may use the bias current as reference and so as to replace the original reference current generated by a bandgap reference circuit, so as to obtain a stable reference current that is not interfered by noise. Moreover, the IC structure of the invention may release the pin which connected to an external impedance to other circuit (for example, a digital circuit) after the IC test process, or disconnect an electrical connection between the bandgap reference circuit and a contact of the IC circuit, so as to reduce the number of pins used in the IC and save the chip size. Various embodiments coping with the spirit of the invention are provided below, though the invention is not limited to the provided embodiments.

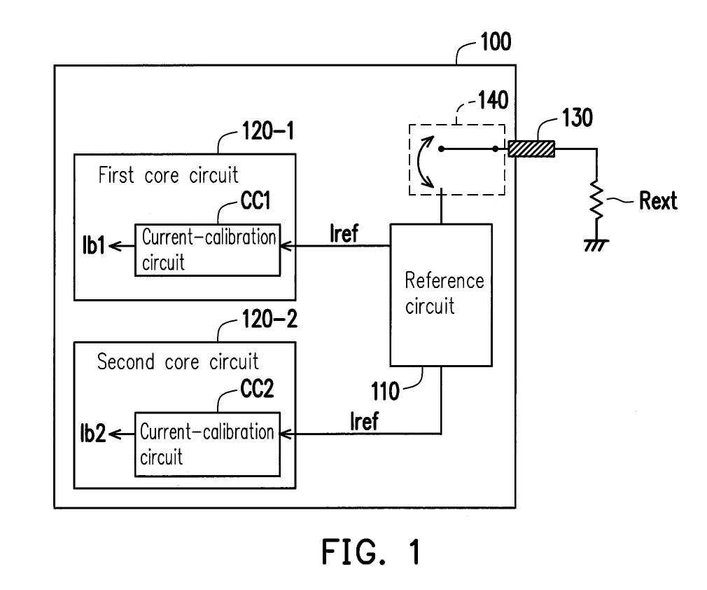

FIG. 1 is a schematic diagram of an IC structure 100 according to a first embodiment of the invention. The IC structure 100 of the present embodiment is disposed on a circuit substrate, for example, a printed circuit board. The IC structure 100 mainly includes a reference circuit 110 and at least two core circuits (for example, a first core circuit 120-1 and a second core circuit 120-2). The reference circuit 110 generates a reference current Iref. The core circuits 120-1 and 120-2 can be silicon intellectual property (SIP) devices, or function circuits independent to each other. To facilitate description, only the two core circuits 120-1 and 120-2 are illustrated in FIG. 1, though the number of the core circuits can be adjusted according to an actual requirement of a user.

Current paths between the reference circuit 110 and the core circuits 120-1 and 120-2 are still interfered by noises from a power terminal/ground terminal of the SIP device or other signal noises to cause unstableness of the reference current Iref, so that in the embodiment of the invention, current-calibration circuits CC1 and CC2 are respectively configured in each of the core circuits 120-1 and 120-2, and the current-calibration circuits CC1 and CC2 may generate bias currents Ib1 and Ib2 in the respective core circuits 120-1 and 120-2 according to the reference current Iref. In the present embodiment, current values of the bias currents Ib1 and Ib2 are substantially equal to a current value of the reference current Iref. In this way, in the embodiment of the invention, since the current-calibration circuits CC1 and CC2 are configured internally in the corresponding core circuits 120-1 and 120-2, the external noise interference cannot influence the current-calibration circuits CC1 and CC2. Moreover, the core circuits 120-1 and 120-2 and the respective current-calibration circuits CC1 and CC2 have the same power terminal and the ground terminal. Therefore, compared to the reference current Ira, the bias currents Ib1 and Ib2 are more stable and are not influenced by noise interference. Therefore, the bias currents Ib1 and Ib2 may replace the original reference current Iref, the core circuits 120-1 and 120-2 may guarantee operation stableness thereof

In a IC test process of the IC structure 100 of the embodiment of the invention before shipment, the reference circuit 110 is electrically connected to an external impedance Rext which exposes outside the IC structure 100 through a portion of pin 130 of the IC structure 100, and the reference circuit 110 generates the stable reference current Iref, and the current-calibration circuits CC1 and CC2 generate the bias currents Ib1 and Ib2 accordingly. In another embodiment, the reference circuit 110 may record a current value of the reference current Iref through an internal memory device thereof Moreover, after the IC test process of the IC structure 100 performed before shipment (probably before the IC structure 100 is shipped to other company), a connection between the reference circuit 110 and the pin 130 of the IC structure 100 can be disconnected through a switch 140 (which can be implemented by a multiplexer). In this way, the pin 130 can be provided to other circuits of the IC structure 100, or the external impedance Rext is removed after the aforementioned IC test process, such that the IC structure 100 may reduce the pin count and save the chip size. Moreover, since the reference circuit 110 or the current-calibration circuits CC1/CC2 may record the current value through an internal memory device thereof, a test time of the IC structure 100 is saved. Functions of various components of the embodiment of the invention are described in detail below.

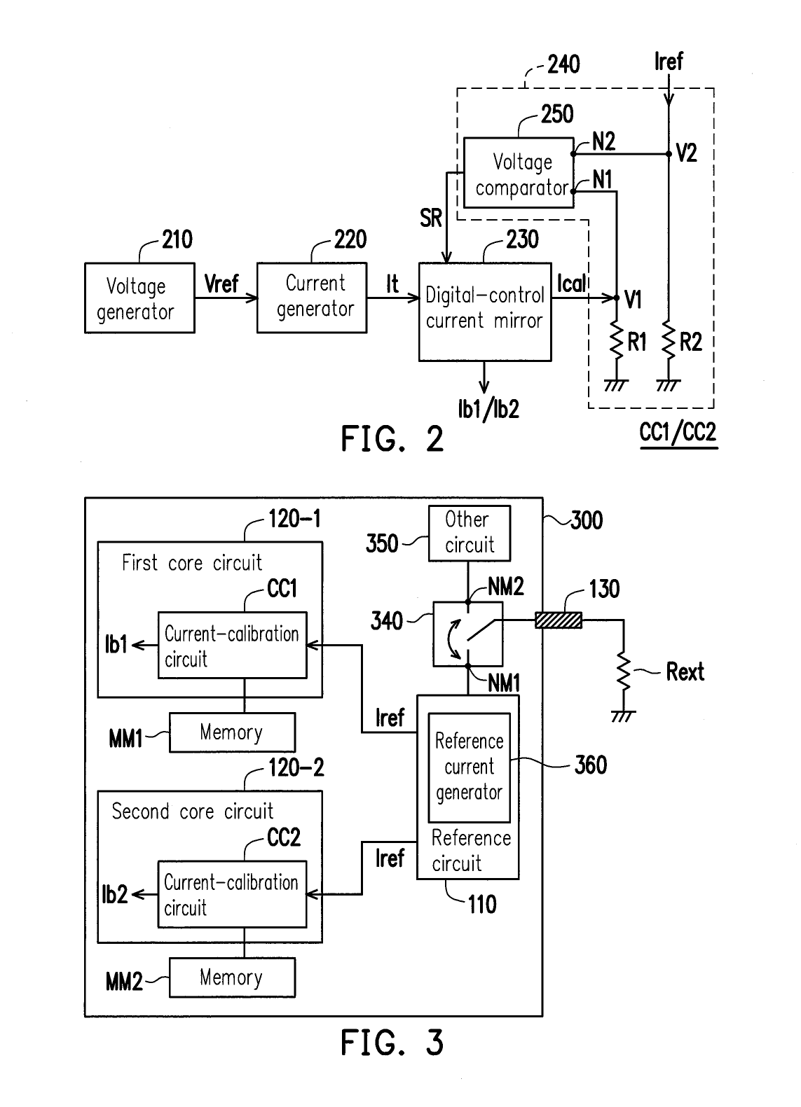

The embodiment of the invention provides a method for implementing the current-calibration circuits CC1 and CC2. FIG. 2 is a block diagram of the current-calibration circuit CC1/CC2 according to the first embodiment of the invention. The current-calibration circuit CC1/CC2 is used for generating the bias current Ib1/Ib2, and calibrates the bias current Ib1/Ib2 according to the reference current Iref. In one embodiment, the current-calibration circuit CC1/CC2 includes a voltage generator 210, a current generator 220, a digital-control current mirror 230 and a current comparator 240. The voltage generator 210 generates an internal reference voltage Vref. The current generator 220 generates an internal reference current It according to the internal reference voltage Vref. In an embodiment, the internal reference voltage Vref is proportional to an absolute temperature, and wherein the temperature coefficient of the current generator 220 is negative, and the current generator 220 has an impedance device having a positive temperature coefficient. The current generator 220 generates the internal reference current. That is independent to the variation of the temperature and the variation of the voltage according to the internal reference voltage Vref.

When the current-calibration circuit CC1/CC2 is activated, the digital-control current mirror 230 generates a calibrating current Ical according to the internal reference current It, and adjusts a current value of the calibrating current Ical. The current comparator 240 is configured to compare the calibrating current Ical and the reference current Iref. The digital-control current mirror 230 generates the bias current Ib1/Ib2 according to a comparison result SR of the current comparator 240, where a current value of the bias current Ib1/Ib2 is substantially the same to a present current value of the reference current Iref.

The digital-control current mirror 230 and the current comparator 240 may have many implementations. A first implementations is that the digital-control current mirror 230 may gradually increase the current value of the calibrating current Ical from a lowest current value. As shown in FIG. 2, the current comparator 240 compares whether the current value of the calibrating current Ical is substantially equal to the current value of the reference current Iref through a voltage comparator 250, a first resistor R1 and a second resistor R2. The current comparator 240 compares a first voltage V1 and a second voltage V2 by using the voltage comparator 250, so as to determine and compare the current value of the calibrating current Ical flowing through the first resistor R1 and the reference current Iref flowing through the second resistor R2, and outputs the comparison result SR. When the current value of the calibrating current Ical is substantially equal to the current value of the reference current Iref, the current comparator 240 enables the comparison result SR. After the digital-control current mirror 230 receives the enabled comparison result SR, it represents that calibration process of the calibrating current Ical is completed, and the digital-control current mirror 230 mirrors the calibrating current Ical to generate the bias current Ib1/Ib2. Namely, the current value of the bias current Ib1/Ib2 is substantially the same to the present current value of the reference current Iref. Namely, the digital-control current mirror 230 may gradually increase calibrating current Ical, and the current comparator 240 may determine whether the present current value of the calibrating current Ical is substantially equal to the current value of the reference current Iref.

A second implementations is that the digital-control current mirror 230 may provide the calibrating current Ical from a predetermined highest current value, and gradually decreases the current value, and the current comparator 240 compares the current values of the calibrating current Ical and the reference current Iref. In other implementations, the other embodiments of the invention may use the digital-control current mirror 230 and the current comparator 240 to gradually approach the current values of the calibrating current Ical and the reference current Iref through a dichotomy gradual approximation method (or referred to as a binary weight method) or a successive approximation (SAR) method until the two current values are substantially equivalent.

FIG. 3 is a schematic diagram of an IC structure 300 according to a second embodiment of the invention. Besides the various components in the IC structure 100 of FIG. 1, the IC structure 300 further includes a multiplexer 340, other circuit 350 and memories MM1 and MM2 respectively corresponding to the current-calibration circuits CC1/CC2. The reference circuit 110 includes a reference current generator 360, which can be implemented by a bandgap reference circuit. In the present embodiment, the current-calibration circuits CC1/CC2 may record calibrated current values (which are, for example, digital calibrating values in an embodiment) of the calibrated bias currents Ib1 and Ib2 through the corresponding memory devices (for example, the memories MM1/MM2) disposed in the IC structure 300. A first connection terminal NM1 of the multiplexer 340 is coupled to the reference current generator 360 in the reference circuit 110, and a second connection terminal NM2 of the multiplexer 340 is coupled to the other circuit 350 in the IC structure 300. An output connection terminal of the multiplexer 340 is coupled to the pin 130 of the IC structure 300.

In the IC test process of the IC structure 300 before shipment, the multiplexer 340 electrically connects the first connection terminal NM1 to the output connection terminal. Thus, the reference current generator 360 is coupled to the external impedance Rext through the pin 130 of the IC structure 300 to generate the accurate reference current Iref. The current-calibration circuits CC1/CC2 generate the bias currents Ib1,/Ib2 in the core circuits 120-1,/120-2 according to the reference current Iref, and record the calibrated current values of the bias currents Ib1/Ib2 in the memories MM1/MM2. After the IC test process, the multiplexer 340 electrically connects the second connection terminal NM2 to the output connection terminal. In this way, the external impedance Rext only appears in the IC test process of the IC structure 300 to assist generating the reference current Iref, and after the IC test process, the external impedance Rext can be removed, so as to reduce the pin count used by the IC structure 300. In some embodiments, since the other circuit in the IC structure 300 probably requires the external impedance Rext to maintain a normal operation thereof, after the IC test process, the external impedance Rext can also be employed by the other circuit 350, by which the pin count used in the IC structure can also be reduced. Therefore, the current calibration circuits CC1/CC2 may generate the bias currents Ib1/Ib2 according to the calibrated current values recorded by the memories MM1/MM2 without continually referring to the reference current Iref to calibrate the bias currents Ib1/Ib2.

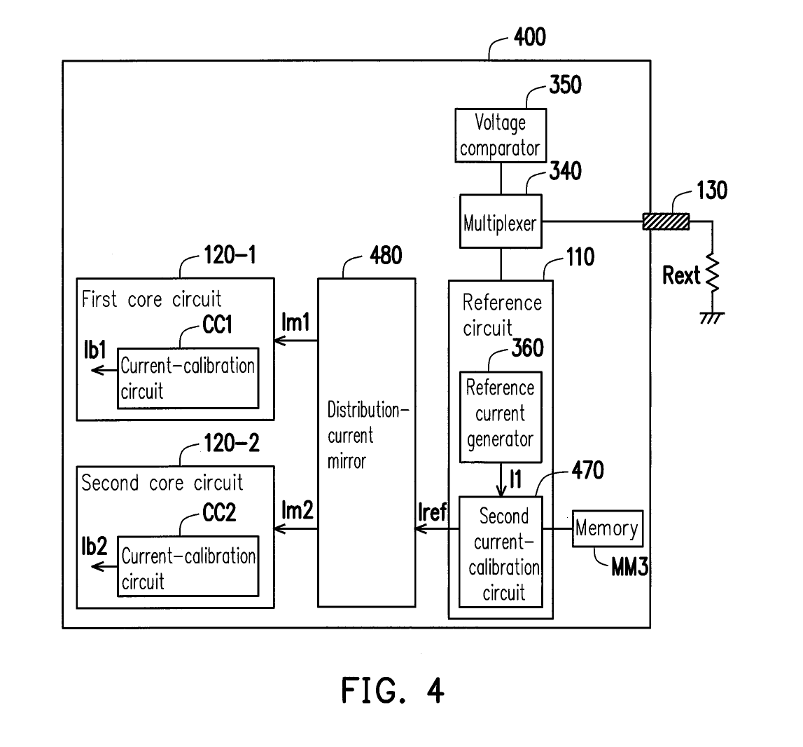

FIG. 4 is a schematic diagram of an IC structure 400 according to a third embodiment of the invention. A difference between the IC structure 400 of FIG. 4 and the IC structure 300 of FIG. 3 is that the reference circuit 110 of the IC structure 400 further includes a second current-calibration circuit 470 besides the reference current generator 360. The IC structure 400 is further configured with a memory MM3 for the use of the second current-calibration circuit 470, and does not include the memories MM1/MM2 shown in FIG. 3. The second current-calibration circuit 470 can be implemented by the current-calibration circuit CC1/CC2 of FIG. 2. In detail, when the second current-calibration circuit 470 is implemented, a first current I1 of FIG. 4 is regarded as the reference current Iref of FIG. 2 to serve as an input current of the second current-calibration circuit 470, and the reference current Iref of FIG. 4 is regarded as the bias currents Ib1/Ib2 of FIG. 2 to serve as an output current of the second current-calibration circuit 470. In the embodiment of FIG. 4, the reference current generator 360 is used for generating the first current I1 when the reference current generator 360 electrically connects the external impedance Rext. The second current-calibration circuit 470 is coupled to the reference current generator 360 to receive the first current I1. The second current-calibration circuit 470 uses the memory MM3 to record the calibrated current value of the first current I1, and generates the reference current Iref according to the recorded calibrated current value, and transmits the reference current Iref to a distribution-current mirror 480. The distribution-current mirror 480 is coupled between the reference circuit 110 and the at least two core circuits 120-1, 120-2. The distribution-current mirror 480 is configured to receive the reference current Iref to generate a plurality of mirror-mapping currents Im1, Im2 to the core circuits 120-1 and 120-2, such that the mirror-mapping currents Im1, Im2 serve as reference currents of the core circuits 120-1, 120-2 respectively. The current-calibration circuits CC1/CC2 respectively generate the bias currents Ib1/Ib2 according to the mirror-mapping currents Im1, Im2.

Since the calibrated current value of the first current I1 is recorded in the memory MM3, each time when the reference circuit 110 of FIG. 4 is activated, the second current-calibration circuit 470 first generates the accurate reference current Iref according to the calibrated current value recorded in the memory MM3, and then the current-calibration circuits CC1/CC2 adjust the bias currents Ib1/Ib2 thereof according to the mirror-mapping currents Im1, Im2 mapped by the reference current Iref. Therefore, the number of the memories required by the IC structure 400 (for example, the IC structure 400 requires one memory MM3 is less than the number of the memories used in the IC structure 300 of FIG. 3 (for example, the IC structure 300 requires two memories MM1/MM2). However, a time required for the IC structure 400 stabilizing the bias currents Ib1/Ib2 after each activation is probably longer than a time required for the IC structure 300 of FIG. 3 stabilizing the bias currents Ib1/Ib2, so that the current-calibration circuits CC1/CC2 in the IC structure 400 are required to be calibrated according to the mirror-mapping current Im1, Im2 mapped by the reference current Iref.

In summary, in the IC structure of the invention, the current-calibration circuit is configured in each of the core circuits, such that each of the core circuits is adapted to generate the bias current generated by the current-calibration circuit according to the reference current, so as to replace the original reference current generated by the bandgap reference circuit. Besides that the reference current generated by the IC of the invention is not influenced by a variation of an absolute temperature and a variation of a system voltage, a process offset is also eliminated to obtain the stable reference current that is not interfered by noise. Moreover, the IC structure of the invention may remove the external impedance after the IC test process or release the pin for the use of other digital circuit, so as to reduce the number of pins used in the IC and save the chip size.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An integrated circuit structure, comprising:
a reference circuit, generating a reference current; and
at least two core circuits, coupled to the reference circuit for receiving the reference current,
wherein each of the core circuits comprises:
a current-calibration circuit, generating a bias current according to the reference current,
the core circuit uses the bias current as reference so as to replace the reference current which generated by the reference circuit,
wherein in an IC test process, the reference circuit is electrically connected to an external impedance through a pin of the integrated circuit structure to generate the reference current, and after the IC test process, a connection between the reference circuit and the pin of the integrate circuit structure is disconnected.

2. The integrated circuit structure as claimed in claim 1, wherein the current-calibration circuit comprises:
a voltage generator, configured to generate an internal reference voltage;
a current generator, coupled to the voltage generator, and generating an internal reference current according to the internal reference voltage;
a digital-control current mirror, coupled to the current generator, and generating a calibrating current according to the internal reference current; and
a current comparator, coupled to the digital-control current mirror, and configured to compare the reference current with the calibrating current,
wherein when the current-calibration circuit is activated, the digital-control current mirror adjusts a current value of the calibrating current,
the digital-control current mirror generates the bias current according to a comparison result of the current comparator, wherein a current value of the bias current is substantially the same as a present current value of the reference current.

3. The integrated circuit structure as claimed in claim 2, wherein the internal reference voltage is proportional to an absolute temperature, and
the current generator comprises an impedance device having a positive temperature coefficient, and the current generator generates the internal reference current that is independent to a variation of the absolute temperature and a variation of a system voltage according to the internal reference voltage.

4. The integrated circuit structure as claimed in claim 3, further comprising a memory corresponding to each of the current-calibration circuits, the memory is configured to record a calibrated current value of the calibrated bias current.

5. The integrated circuit structure as claimed in claim 4, wherein the reference circuit comprises a reference current generator,
wherein in the IC test process, the reference current generator of the integrated circuit structure is coupled to the external impedance through the pin of the integrated circuit structure to generate the reference current, and the current-calibration circuit generates the bias current in the at least one core circuit according to the reference current, and record a calibrated current value of the bias current in the memory,
wherein the current-calibration circuit generates the bias current according to the calibrated current value recorded by the memory.

6. The integrated circuit structure as claimed in claim 1, further comprising a memory, and
the reference circuit comprising:
a reference current generator, configured to generate a first current; and
a second current-calibration circuit, coupled to the reference current generator,
wherein the second current-calibration circuit uses the memory to record a calibrated current value of the first current, and generates the reference current according to the recorded calibrated current value.

7. The integrated circuit structure as claimed in claim 6, wherein in the IC test process, the reference current generator is coupled to the external impedance through the pin of the integrated circuit structure to generate the first current, and the second current-calibration circuit records the calibrated current value of the first current,
the current-calibration circuit generates the bias current according to the reference current generated by the second current-calibration circuit.

8. The integrated circuit structure as claimed in claim 1, further comprising:
a distribution-current mirror, coupled between the reference circuit and the at least two core circuits, the distribution-current mirror configured to receive the reference current and to generate a plurality of mirror-mapping currents to the core circuits to serve as the reference current of the core circuits respectively.

9. The integrated circuit structure as claimed in claim 1, further comprising:
a multiplexer, having a first connection terminal coupled to the reference circuit, a second connection terminal coupled to a digital circuit in the integrated circuit structure, and an output connection terminal coupled to the pin of the integrated circuit structure, wherein a portion of the pin which expose outside the integrated circuit structure is electrically connected to the external impedance,
wherein in the IC test process, the multiplexer electrically connects the first connection terminal to the output connection terminal, and
after the IC test process, the multiplexer electrically connects the second connection terminal to the output connection terminal.
